(19) United States
(12) Patent Application Publication
(10) Pub. No.: US 2019/0157332 A1
(43) Pub. Date: May 23, 2019

(54) Back-side Illumination CMOS Image Sensor and Forming Method Thereof

(71) Applicant: Huaian Imaging Device Manufacturer Corporation, Huaian (CN)

(72) Inventors: Haifeng LONG, Huaian (CN); Tianhui LI, Huaian (CN); Xiaolu HUANG, Huaian (CN)

(21) Appl. No.: 16/149,469

(22) Filed: Oct. 2, 2018

(30) Foreign Application Priority Data
Nov. 17, 2017 (CN) 201711146060.4

(51) Int. Cl. H01L 27/146

(52) U.S. Cl. CPC H01L 27/14629; H01L 27/1464; H01L 27/1463; H01L 27/14621; H01L 27/14685; H01L 27/14627; H01L 27/14625

(57) ABSTRACT

A back-side illumination CMOS image sensor and a method forming it are described. A first refraction layer, a reflection layer, and a second refraction layer are deposited in the dielectric layer around the isolation trench between pixels in the image sensor. The refractive index of the second refraction layer is smaller than the refractive index of a dielectric layer to reduce the refraction of light due to total reflection. And a small amount of light refracted by the second refraction layer is reflected back to the second refraction layer the reflection layer, and thus this part of light is collected to a photodiode region to prevent the light cross-talk to an adjacent photodiode. More photons are absorbed resulting in higher quantum conversion efficiency.

### CROSS REFERENCES TO RELATED APPLICATIONS

This application claims the benefit of priority to Chinese Patent Application No. CN201711146060.4, entitled “Back-Side Illumination CMOS Image Sensor and Forming Method Thereof”, filed with SIPO on Nov. 17, 2017, the contents of which are incorporated herein by reference in its entirety.

### TECHNICAL FIELD

The present disclosure relates to the field of imaging, and in particular, to a back-side illumination CMOS image sensor and a forming method thereof.

### BACKGROUND

Image sensors are developed based on a photoelectric technology. The image sensors are sensors that can sense optical image information and convert it into usable output signals.

Image sensors can be divided into charge-coupled device image sensors (also referred to as CCD image sensors) and CMOS (Complementary Metal Oxide Semiconductor) image sensors according to their characteristics, wherein the CMOS image sensors are manufactured based on a complementary metal oxide semiconductor (CMOS) device technology. Since the CMOS image sensors are manufactured using a conventional CMOS device process, the image sensors and their required peripheral circuits can be integrated, so that the CMOS image sensors have a wider application prospect.

The CMOS image sensors are divided into a front-side illumination type and a back-side illumination type. A conventional CMOS image sensor on a mobile phone takes images from its non-screen surface, a more frequently used mode called front-illumination type, To switch to and optimize the back-side illumination type involves changing the internal structure, a photosensitive layer is redirected, such that light may enter from a back surface, thereby preventing the light from being affected by circuits and transistors placed between micro lenses and photodiodes in a conventional CMOS image sensor structure, thereby significantly increasing the efficiency of the light absorption and greatly improving the picture taking effect under a low illumination condition.

FIG. 1a shows a conventional structure diagram of a back-side illumination CMOS image sensor. The back-side illumination CMOS image sensor includes: a front-end structure 1, the front-end structure 1 including a circuit layer 2 and a dielectric layer 3, as well as photodiodes 4 and deep trench isolation structures which includes a refraction layer 5 formed in the dielectric layer, and a filter layer 6 and a micro lens layer 7 subsequently formed on the front-end structure 1. Incident light (image) passes through the micro lens layer 7 and the filter layer 6 to reach the dielectric layer 3, then is reflected by the refraction layer 5 in the trench isolation structures, and is finally absorbed by the photodiodes 4, wherein the amount of absorbed photons can limit light intensity on the image sensor thereby affects the imaging quality.

FIG. 1b shows a light path of the conventional back-side illumination CMOS image sensor in FIG. 1a. Light a from top (shown here as left) reaches at the interface between the dielectric layer 3 and the refraction layer 5 at an input angle smaller than the Brewster Angle goes through a totally internal reflection, without ever entering the photodiodes 4. Incident light b at an input angle larger than the Brewster Angle is refracted in the refraction layer 5, and part of the light goes through secondary refractions by the refraction layer 5, so that this part of light cannot be absorbed by the photodiodes 4.

However, with stronger demand for miniaturization an effective area of photodiodes continuously reduces, so does the percentage area that can absorb light. In addition, electronic interference and thermally induced dark currents are on the rise, but photoelectric conversion efficiency has decreased significantly. Therefore the incident light loss from secondary refractions in the refraction layer becomes even more challenging. The problem to be solved by the present disclosure is how to improve the photoelectric conversion efficiency.

### SUMMARY

The present disclosure provides a back-side illumination CMOS image sensor, including a front-end structure, wherein the front-end structure comprises: a dielectric layer having a first and a second surfaces opposing to each other: a photodiode disposed on the first surface of the dielectric layer; a circuit layer bonded to the first surface of the dielectric layer; a deep trench isolation structure is patterned on the second surface of the dielectric layer defined by an opening of a mask layer; a first refraction layer disposed on the second surface of the dielectric layer including a bottom and side walls of the deep trench isolation structure; a reflection layer disposed directly on the first refraction layer at the bottom and side walls of the deep trench isolation structure; and a second refraction layer disposed on the second surface of the dielectric layer and filling the deep trench isolation structure; wherein a refractive index of the first refraction layer is smaller than a refractive index of the dielectric layer; and a pixel element bonded to the second surface of the dielectric layer.

Optionally the deep trench isolation structure exposes the first surface of the dielectric layer.

Optionally each pixel element comprises a filter layer and a micro lens layer.

Optionally there is an absorption layer on the second refractive layer.

Optionally there is an anti-reflection layer between the first refractive layer and the second surface of the dielectric layer.

Another embodiment of the disclosure provides a method of forming a back-side illumination CMOS image sensor, comprising: providing a substrate; depositing a dielectric layer on the substrate, wherein the dielectric layer has a first and a second surfaces opposing to each other: providing a photodiode on the first surface of the dielectric layer; providing a circuit layer bonded to the first surface of the dielectric layer; patterning a deep trench isolation structure on the second surface of the dielectric layer defined by an opening of a mask layer; depositing a first refraction layer on the second surface of the dielectric layer and a bottom and side walls of the deep trench isolation structure; depositing a reflection layer directly on the first refraction layer only at the bottom and side walls of the deep trench isolation structure; depositing a second refraction layer on the second surface of the dielectric layer filling the deep trench isolation structure; wherein a refractive index of the first refraction layer is smaller than a refractive index of the dielectric layer; and bonding a pixel element to the second surface of the dielectric layer.

Optionally a material of the dielectric layer comprises one of silicon, silicon oxide and silicon nitride.

Optionally a material of the second refraction layer comprises silicon oxide.

Optionally a material of the first refraction layer comprises one or a combination of silicon and silicon oxide.

Optionally a material of the reflection layer comprises one or a combination of aluminum and silver.

Optionally depositing the second refraction layer comprises a process of physical vapor deposition, chemical vapor deposition, plasma enhanced chemical vapor deposition, atomic layer deposition or electroplating.

Optionally depositing the reflection layer comprises a process of physical vapor deposition, chemical vapor deposition, plasma enhanced chemical vapor deposition, atomic layer deposition or electroplating.

Optionally depositing a reflection layer directly on the first refraction layer only at the bottom and side walls of the deep trench isolation structure comprises depositing the reflection layer on the first refractive layer first and then removing a portion outside the deep trench isolation structure.

Optionally depositing the second refractive layer comprises applying a process of physical vapor deposition, chemical vapor deposition, plasma enhanced chemical vapor deposition, atomic layer deposition or electroplating.

Optionally a portion of the second refraction layer deposited outside the deep isolation trench structure is removed afterwards.

### BRIEF DESCRIPTION OF THE DRAWINGS

FIG. 1a shows a structure diagram of a conventional back-side illumination CMOS image sensor.

FIG. 1b shows a light path diagram of the conventional back-side illumination CMOS image sensor.

FIG. 2 to FIG. 9 show schematic diagrams of intermediate structures during a forming process of a back-side illumination CMOS image sensor according to an embodiment of the present disclosure, in which:

FIG. 2 shows a schematic diagram of a front-end structure;

FIG. 3 shows a schematic diagram of forming the deep trenches;

FIG. 4 shows a schematic diagram of forming a second refraction layer;

FIG. 5 shows a schematic diagram of forming a reflection layer;

FIG. 6 shows a schematic diagram after the extra second reflection layer and the extra reflection layer outside the deep trenches are removed;

FIG. 7 shows a schematic diagram after the first refraction layer is disposed;

FIG. 8 shows a schematic diagram after the extra first refraction layer outside the deep trenches is removed;

FIG. 9 shows a schematic diagram of the back-side illumination CMOS image sensor according to the embodiment of the present disclosure.

FIG. 10 shows a light path diagram of the back-side illumination CMOS image sensor according to the embodiment of the present disclosure.

### DESCRIPTION OF COMPONENT MARK NUMBERS

1, 100 front-end structure
2, 101 circuit layer
3, 200 dielectric layer
4, 201 photodiode
5 refraction layer
202 mask layer
203 second refraction layer
204 reflection layer
205 first refraction layer
6, 206 filter layer
7, 207 micro lens layer
a, b light

### DETAILED DESCRIPTION OF THE PREFERRED EMBODIMENTS

The embodiments of the present disclosure will be described below through specific examples. Those skilled in the art could easily understand other advantages and effects of the present disclosure from the content disclosed in this specification. The present disclosure can also be implemented or applied through other different specific embodiments. The details in this specification can also be based on different viewpoints and applications, and various modifications or changes can be made without departing from the spirit of the present disclosure.

See FIG. 2 to FIG. 10. It should be noted that the drawings provided in the embodiments merely illustrate the basic idea of the present disclosure in a schematic manner, the drawings only show components related to the present disclosure but are not drawn according to the number, shape and size of the components during actual implementation, the type, quantity and proportion of each component can be changed arbitrarily during actual implementation, and the component layout pattern may also be more complicated.

### Embodiment 1

As shown in FIG. 9, this embodiment provides a back-side illumination CMOS image sensor, comprising a front-end structure 100, deep trench isolation structures, and pixel elements.

The front-end structure 100 comprises a dielectric layer 200 and a circuit layer 101 bonded to a first surface of the dielectric layer 200. The dielectric layer 200 has photodiodes 201 therein, and the dielectric layer 200 further comprises a second surface opposite to the first surface.

As an example, a material of the dielectric layer 200 comprises one of silicon, silicon oxide and silicon nitride.

As an example, a material of the second refraction layer 203 comprises silicon oxide.

The higher a refractive index of the material is, the stronger the ability to refract incident light is. Therefore, light is emitted from an optically denser medium to an optically thinner medium, and an incident angle is greater than a critical angle, a total reflection phenomenon may occur. Thus, in this embodiment, a material of the dielectric layer 200 is preferably low-cost silicon having a higher refractive index (approximately 3.42) as an optically dense medium, and silicon oxide having a lower refractive index (approximately 1.55) is used as an optically thin medium.

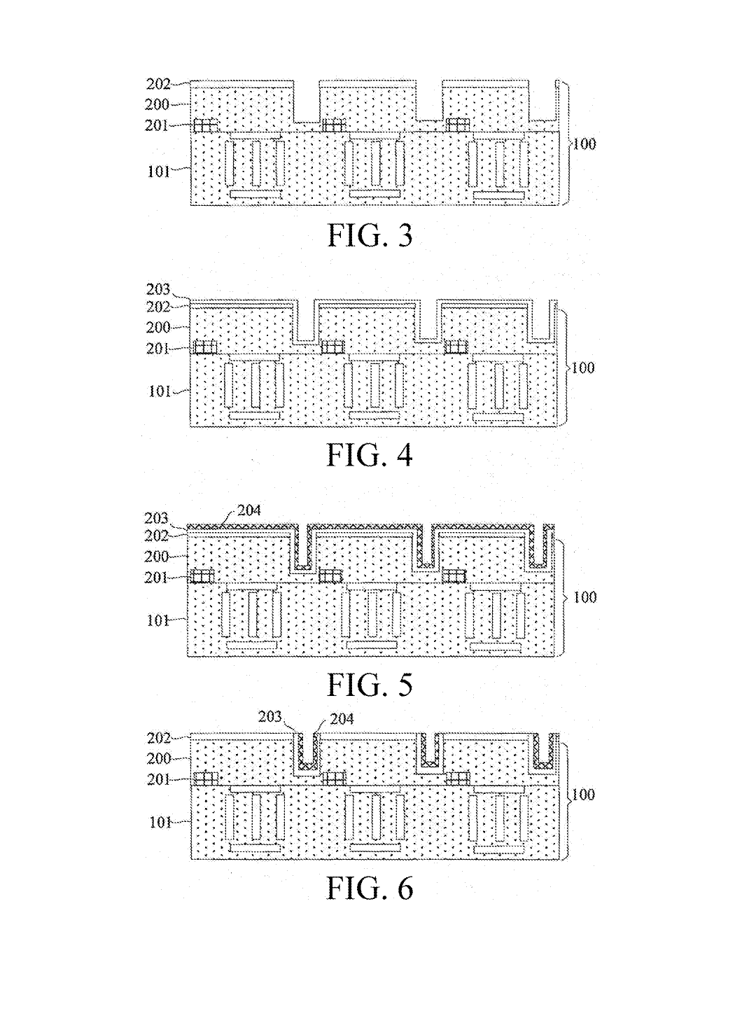

In embodiment 1, the dielectric layer 200 further comprises a mask layer 202 deposited on the second surface thereof. The mask layer 202 is made of silicon nitride or silicon oxide. In embodiment 1, the mask layer 202 is preferably made of silicon nitride. The dielectric layer 200 is etched through a mask window to form a plurality of trenches arranged regularly and in parallel in the dielectric layer 200, as shown in FIG. 3.

The deep trench isolation structures start from the second surface of the dielectric layer 200, and extend toward the first surface of the dielectric layer 200. Each deep trench isolation structure comprises a first refraction layer 205, a reflection layer 204 surrounding a bottom surface and a lateral surface of the first refraction layer 205, and a second refraction layer 203 surrounding a bottom surface and a lateral surface of the reflection layer 204. Top surfaces of the first refraction layer 205, the reflection layer 204 and the second refraction layer 203 are all flush with the second surface of the dielectric layer 200, and a refractive index of the second refraction layer 203 is smaller than a refractive index of the dielectric layer 200.

In this embodiment, the deep trench isolation structures start from a surface of the mask layer 202 on the second surface of the dielectric layer 200, extend toward the first surface of the dielectric layer 200, and are surrounded by the dielectric layer 200. As an example, the deep trench isolation structures may have a distance from the first surface of the dielectric layer 200, and also may extend to the first surface of the dielectric layer 200.

As an example, materials of the reflection layer 204 comprise one of aluminum and silver, or a combination thereof. In this embodiment, low-cost aluminum is selected as the material of the reflection layer 204. The refractive index of the second refraction layer 203 is smaller than the refractive index of the dielectric layer 200 where the photodiodes 201 are located, light can be emitted from an optically dense medium to an optically thin medium, and the refraction of the light is reduced from total internal reflection (Snell's law), but a small amount of light still can be refracted to an adjacent photodiode 201 region through the second refraction layer 203. This part of light may be reflected back to the second refraction layer 203 through the reflection layer 204, and thus this part of light is collected into a photodiode 201 region, such that the resultant photoelectric conversion efficiency is improved.

As an example, materials of the first refraction layer 205 comprise one of silicon and silicon oxide, or a combination thereof. In this embodiment, low-cost silicon is preferred as the material of the first refraction layer 205.

The pixel elements are bonded to the second surface of the dielectric layer 200.

As an example, each pixel element comprises a filter layer 206 and a micro lens layer 207. In this embodiment, the filter layer 206 is formed on the mask layer 202 on the second surface of the dielectric layer 200. The filter layer 206 has a plurality of filters (not shown) thereon. Each filter allows only a specific color of incident light to pass.

The micro lens layer 207 is provided on the filter layer 206, these micro lenses are provided on the corresponding filters, and the filters and the micro lenses jointly constitute pixel units.

As an example, the micro lens layer 207 may be made of an oxide or an organic material, and the micro lens layer 207 is patterned by an exposure and development process. Afterwards, the patterned micro lens layer 207 is treated by a reflux process to obtain lens with convex surfaces. The lens plays a role in condensing light. The curvature radius of the convex surface can be controlled by controlling temperature in the reflux process to achieve a better light condensing effect.

As an example, one of an absorption layer and an anti-reflection layer, or a combination thereof is further comprised between the pixel elements and the dielectric layer, and these layers can be prepared according to specific requirements, which is not be repeatedly described herein.

According to the back-side illumination CMOS image sensor provided in the present disclosure, on the one hand, the refractive index of the second refraction layer is smaller than the refractive index of the dielectric layer, and the refraction of light is reduced using the principle of total reflection; on the other hand, a small amount of light refracted by the second refraction layer is reflected back to the second refraction layer through the reflection of the reflection layer, and this part of light is collected to the photodiode region to prevent the light from being cross-talked to the adjacent photodiode region; therefore, the photoelectric conversion efficiency can be improved.

### Embodiment 2

The present disclosure further provides a forming method of a back-side illumination CMOS image sensor, comprising the following steps:

S1: providing a front-end structure 100, the front-end structure 100 comprises a dielectric layer 200 and a circuit layer 101 bonded to a first surface of the dielectric layer 200, the dielectric layer 200 has photodiodes 201 therein, and the dielectric layer 200 further comprises a second surface opposite to the first surface;

S2: forming deep trenches in the dielectric layer 200, the deep trenches are opened from the second surface of the dielectric layer 200 and extend toward the first surface of the dielectric layer 200;

S3: successively forming a second refraction layer 203, a reflection layer 204 and a first refraction layer 205 in the deep trenches, wherein the reflection layer 204 surrounds a bottom surface and a lateral surface of the first refraction layer 205, the second refraction layer 203 surrounds a bottom surface and a lateral surface of the reflection layer 204, top surfaces of the first refraction layer 205, the reflection layer 204 and the second refraction layer 203 are all flush with the second surface of the dielectric layer 200, and a refractive index of the second refraction layer 203 is smaller than a refractive index of the dielectric layer 200; and

S4: forming pixel elements on the second surface of the dielectric layer 200.

Please refer to FIG. 2 to FIG. 9, which show schematic diagrams of the back-side illumination CMOS image sensor in the present disclosure during forming. FIG. 2 shows a schematic diagram of the front-end structure 100. As an example, a forming method of the front-end structure 100 is well known to those skilled in the art, and is not repeatedly described herein.

As an example, a material of the dielectric layer 200 comprises one of silicon, silicon oxide and silicon nitride. The higher a refractive index of the material is, the stronger the ability to refract incident light is. Therefore, when light is emitted from an optically denser medium to an optically thinner medium, an incident angle is greater than a critical angle, a total reflection phenomenon may occur. Thus, in this embodiment, the material of the dielectric layer 200 is preferably low-cost silicon having a higher refractive index (approximately 3.42) as an optically dense medium.

In embodiment 2, the dielectric layer 200 further comprises a mask layer 202 deposited on the second surface thereof. A method for depositing the mask layer 202 comprises chemical vapor deposition or physical vapor deposition, and in embodiment 2, chemical vapor deposition is preferred. The mask layer 202 is coated with a photoresist (not shown), is exposed and developed, a portion of the mask layer 202 not covered by the photoresist is then etched to form a mask window, and the photoresist is finally removed. Photolithography and etching processes are not repeatedly described herein. The mask layer 202 is made of silicon nitride or silicon oxide. In embodiment 2, the mask layer 202 is preferably made of silicon nitride. The dielectric layer 200 is etched through the mask window to form a plurality of trenches arranged regularly and in parallel in the dielectric layer 200, as shown in FIG. 3. The etching process is dry etching, wherein the dry etching at least includes plasma etching or reactive ion etching. In embodiment 2, the dielectric layer 200 is etched by reactive ion etching.

In this embodiment, the deep trench isolation structures start from a surface of the mask layer 202 on the second surface of the dielectric layer 200, extend toward the first surface of the dielectric layer 200, and are surrounded by the dielectric layer 200. The deep trench isolation structures may have a distance from the first surface of the dielectric layer 200, or also may extend to the first surface of the dielectric layer 200.

As an example, preparing the deep trench isolation structures comprises the steps of:

1) Forming the second refraction layer 203 on inner surfaces of the deep trenches by a process of physical vapor deposition, chemical vapor deposition, plasma enhanced chemical vapor deposition, atomic layer deposition or electroplating. FIG. 4 shows a schematic diagram of forming the second refraction layer 203.

As an example, a material of the second refraction layer 203 comprises silicon oxide. In this embodiment, since a refractive index (approximately 1.55) of silicon oxide is lower than a refractive index of the dielectric layer 200, silicon oxide is preferably used as the material of the second refraction layer 203 to provide an optically thin medium.

2) Forming the reflection layer 204 on an inner surface of the second refraction layer 203 by a process of chemical vapor deposition, plasma enhanced chemical vapor deposition, atomic layer deposition or electroplating. FIG. 5 shows a schematic diagram of forming the refraction layer 204.

As an example, a material of the reflection layer 204 comprises one of aluminum and silver or a combination thereof. In this embodiment, low-cost aluminum is selected as the material of the reflection layer 204. A refractive index of the second refraction layer 203 is smaller than a refractive index of the dielectric layer 200 where the photodiodes 201 are located, light can be emitted from an optically dense medium to an optically thin medium, and the refraction of the light is reduced due to total reflection, but a small amount of light still can be refracted to an adjacent photodiode 201 region through the second refraction layer 203. This part of light may be reflected back to the second refraction layer 203 through the reflection layer 204, and thus this part of light is collected into a photodiode 201 region, so that the photoelectric conversion efficiency is improved.

3) Removing the extra second reflection layer 203 and the extra reflection layer 204 outside the deep trenches. FIG. 6 shows a schematic diagram after the extra second reflection layer 203 and the extra reflection layer 204 outside the deep trenches are removed.

In this embodiment, the extra second reflection layer 203 and the extra reflection layer 204 outside the deep trenches are removed by mechanical grinding and cleaning, and the mask layer 202 is used as a stop layer to protect the dielectric layer 200 and the deep trench isolation structures.

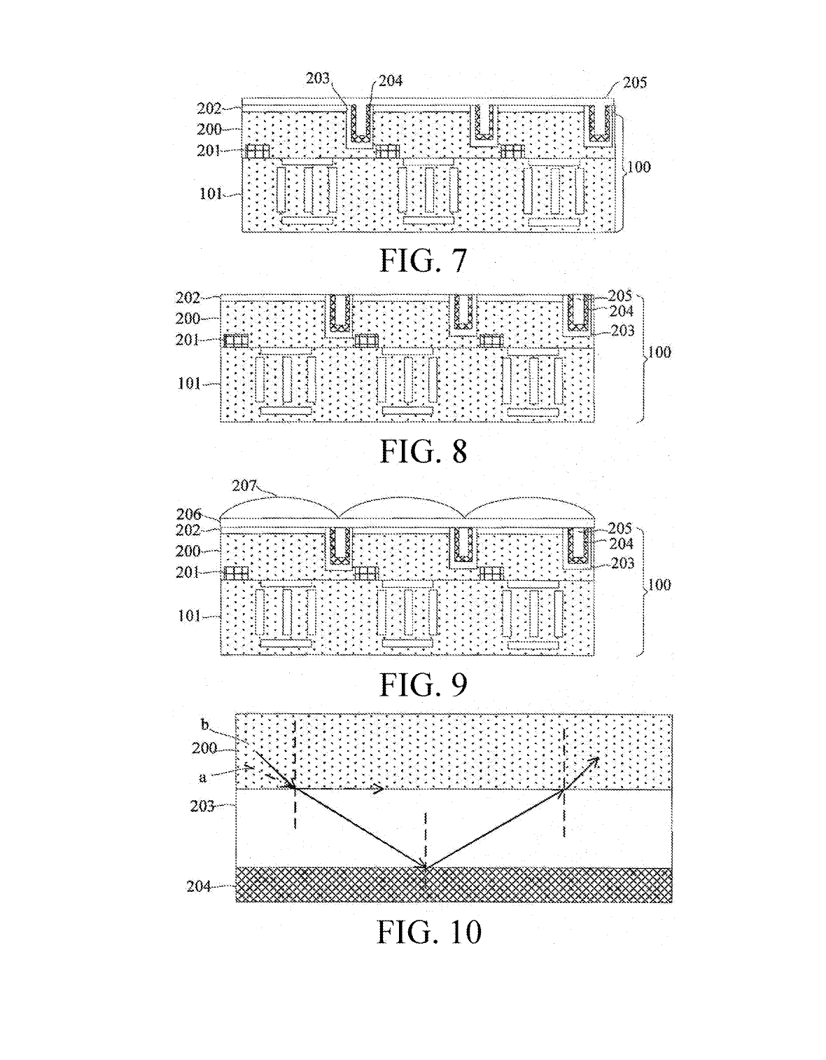

4) Filling an inner surface of the reflection layer 204 with the first refraction layer 205 by a process of physical vapor deposition, chemical vapor deposition, plasma enhanced chemical vapor deposition, atomic layer deposition or electroplating. FIG. 7 shows a schematic diagram after the first refraction layer 205 is filled.

As an example, a material of the first refraction layer 205 comprises one of silicon and silicon oxide or a combination thereof. In this embodiment, low-cost silicon is preferred as the material of the first refraction layer 205.

5) Removing the extra first refraction layer 205 outside the deep trenches. FIG. 8 shows a schematic diagram after the extra first refraction layer 205 outside the deep trenches is removed.

In this embodiment, the extra first refraction layer 205 outside the deep trenches is removed by mechanical grinding and cleaning, and the mask layer 202 is used as a stop layer to protect the dielectric layer 200 and the deep trench isolation structures.

As an example, each pixel element comprises a filter layer 206 and a micro lens layer 207. FIG. 9 shows a structure diagram of the back-side illumination CMOS image sensor according to the present disclosure. In this embodiment, the filter layer 206 is formed on the mask layer 202 on the second surface of the dielectric layer 200. The filter layer 206 has a plurality of filters (not shown) thereon. Each filter allows only a specific color of incident light to pass, and this step will be performed.

The micro lens layer 207 is provided on the filter layer 206, micro lenses corresponding to the filters are provided on the filters, and the filters and the micro lenses jointly constitute pixel units.

As an example, the micro lens layer 207 may be made of an oxide or an organic material, and the micro lens layer 207 is patterned by an exposure and development process. Afterwards, the patterned micro lens layer 207 is treated by a reflux process to obtain lenses with convex surfaces. The lenses play a role in condensing light. The curvature radii of the convex surfaces can be controlled by controlling temperature in the reflux process to achieve a better light condensing effect.

As an example, one or a combination of an absorption layer and an anti-reflection layer is further comprised between the pixel elements and the dielectric layer 200, and these layers can be prepared according to specific requirements, which is not repeatedly described herein.

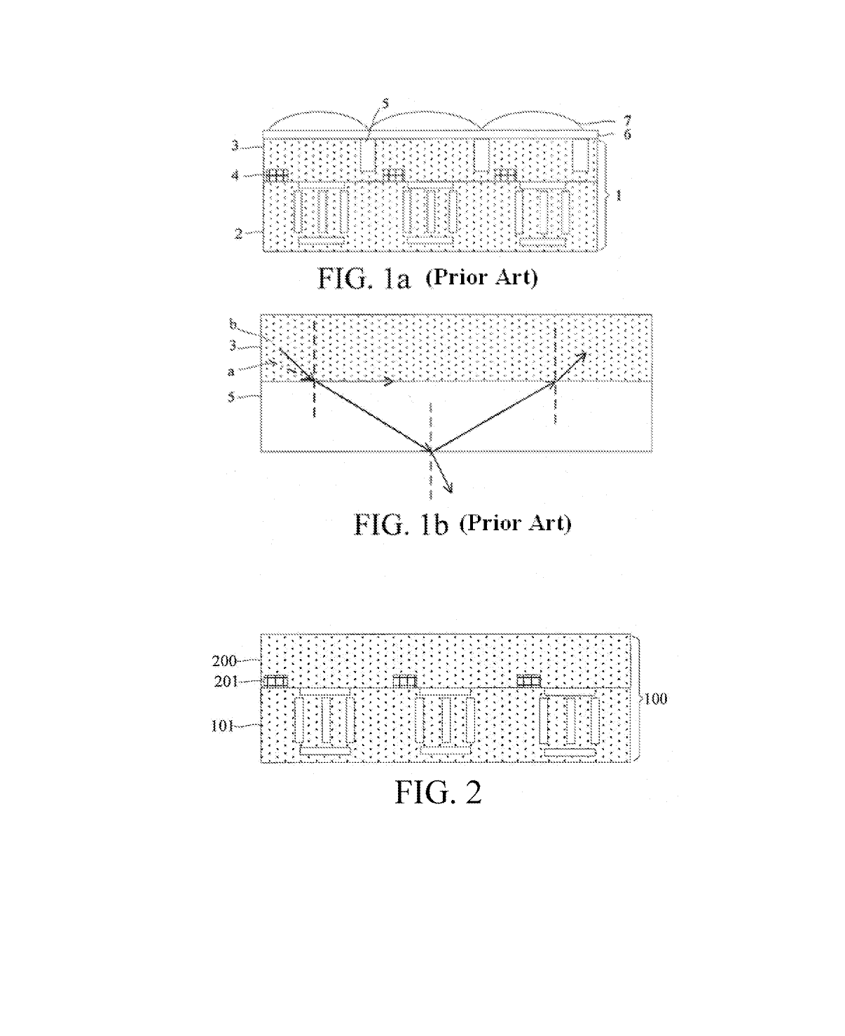

Referring to FIG. 1b and FIG. 10, the advantages of the present disclosure are described as follows.

FIG. 1b shows a light path diagram of a back-side illumination CMOS image sensor in the prior art. Incident light a passes through a dielectric layer 3 and is totally reflected on surfaces of the dielectric layer 3 and a refraction layer 5. Incident light b passes through the dielectric layer 3 and is refracted in the refraction layer 5, and part of the light is secondarily refracted by the refraction layer 5, so that this part of light cannot be absorbed by photodiodes.

FIG. 10 shows a light path diagram of the back-side illumination CMOS image sensor in the present disclosure. Taking the dielectric layer 200 made of silicon, the second refraction layer 203 made of silicon oxide and the reflection layer 204 made of aluminum as an example, incident light a passes through the dielectric layer 200 and is totally reflected on surfaces of the dielectric layer 200 and the second refraction layer 203. Incident light b passes through the dielectric layer 200 and is refracted in the second refraction layer 203, and part of the light is reflected back to the second refraction layer 203 by the reflection layer 204 instead of being secondarily refracted when arriving at a bottom critical surface of the second refraction layer 203, after that, the part of light returns to the dielectric layer 200. The quantity of photons absorbed by photodiodes 201 is improved, so that the quantum conversion efficiency is improved.

The formation method of the back-side illumination CMOS image sensor according to the present disclosure improves the quantity of photons absorbed by the photodiodes, thereby improving the quantum conversion efficiency.

In summary, according to the back-side illumination CMOS image sensor and the forming method thereof provided by the present disclosure, on the one hand, the refractive index of the second refraction layer is smaller than the refractive index of the dielectric layer, and thus the refraction of light is reduced due to total reflection; on the other hand, a small amount of light refracted by the second refraction layer is reflected back to the second refraction layer through the reflection of the reflection layer, and thus this part of light is collected to the photodiode region to prevent the light from being cross-talked to the adjacent photodiode region; thus, the quantity of photons absorbed by the photodiodes is improved, and the quantum conversion efficiency is accordingly improved. Therefore, the present disclosure effectively overcomes various disadvantages in conventional devices, and has a high industrial utilization value.

The above embodiments merely illustrate the principle of the present disclosure and its effects, but are not intended to limit the present disclosure. Any person skilled in the art can modify or change the above embodiments without departing from the spirit and scope of the present disclosure. Accordingly, all equivalent modifications or changes made by those of ordinary skill in the art without departing from the spirit and technical thought disclosed in the present disclosure shall still be covered by the claims of the present disclosure.

What is claimed is:

1. A back-side illumination CMOS image sensor, comprising:
a plurality of pixel units each comprising:
a front-end structure, wherein the front-end structure comprises:
a dielectric layer with a first and a second surfaces opposing to each other:
a photodiode disposed on the first surface of the dielectric layer;
a circuit layer bonded to the first surface of the dielectric layer;
a deep trench isolation structure is patterned on the second surface of the dielectric layer defined by an opening of a mask layer;
a first refraction layer disposed on the second surface of the dielectric layer including a bottom and side walls of the deep trench isolation structure;
a reflection layer disposed directly on the first refraction layer at the bottom and side walls of the deep trench isolation structure; and
a second refraction layer disposed on the second surface of the dielectric layer and filling the deep trench isolation structure;
wherein a refractive index of the first refraction layer is smaller than a refractive index of the dielectric layer;
and
a pixel element bonded to the second surface of the dielectric layer.

2. The back-side illumination CMOS image sensor according to claim 1, wherein the deep trench isolation structure exposes the first surface of the dielectric layer.

3. The back-side illumination CMOS image sensor according to claim 1, wherein each pixel element comprises a filter layer and a micro lens layer.

4. The back-side illumination CMOS image sensor according to claim 1, further comprising an absorption layer on the second refractive layer.

5. The back-side illumination CMOS image sensor according to claim 1, further comprising an anti-reflection layer between the first refractive layer and the second surface of the dielectric layer.

6. A method of forming a back-side illumination CMOS image sensor, comprising:
providing a substrate;
depositing a dielectric layer on the substrate, wherein the dielectric layer has a first and a second surfaces opposing to each other:
providing a photodiode on the first surface of the dielectric layer;
providing a circuit layer bonded to the first surface of the dielectric layer;
patterning a deep trench isolation structure on the second surface of the dielectric layer defined by an opening of a mask layer;
depositing a first refraction layer on the second surface of the dielectric layer and a bottom and side walls of the deep trench isolation structure;
depositing a reflection layer directly on the first refraction layer only at the bottom and side walls of the deep trench isolation structure;
depositing a second refraction layer on the second surface of the dielectric layer filling the deep trench isolation structure;
wherein a refractive index of the first refraction layer is smaller than a refractive index of the dielectric layer;
and
bonding a pixel element to the second surface of the dielectric layer.

7. The method of forming the back-side illumination CMOS image sensor according to claim 6, wherein a material of the dielectric layer comprises one of silicon, silicon oxide and silicon nitride.

8. The formation method of the back-side illumination CMOS image sensor according to claim 6, wherein a material of the second refraction layer comprises silicon oxide.

9. The method of forming the back-side illumination CMOS image sensor according to claim 6, wherein a material of the first refraction layer comprises one or a combination of silicon and silicon oxide.

10. The method of forming the back-side illumination CMOS image sensor according to claim 6, wherein a material of the reflection layer comprises one or a combination of aluminum and silver.

11. The method of forming the back-side illumination CMOS image sensor according to claim 6, wherein depositing the second refraction layer comprises a process of physical vapor deposition, chemical vapor deposition, plasma enhanced chemical vapor deposition, atomic layer deposition or electroplating.

12. The method of forming the back-side illumination CMOS image sensor according to claim 6, wherein depositing the reflection layer comprises a process of physical vapor deposition, chemical vapor deposition, plasma enhanced chemical vapor deposition, atomic layer deposition or electroplating.

13. The method of forming the back-side illumination CMOS image sensor according to claim 6, wherein depositing a reflection layer directly on the first refraction layer only at the bottom and side walls of the deep trench isolation structure comprises depositing the reflection layer on the first refractive layer first and then removing a portion outside the deep trench isolation structure.

14. The method of forming the back-side illumination CMOS image sensor according to claim 6, wherein depositing the second refractive layer comprises applying a process of physical vapor deposition, chemical vapor deposition, plasma enhanced chemical vapor deposition, atomic layer deposition or electroplating.

15. The method of forming the back-side illumination CMOS image sensor according to claim 6, further comprising: removing a portion of the second refraction layer deposited outside the deep isolation trench structure.
